(19) United States
(12) Patent Application Publication
(10) Pub. No.: US 2026/0223735 A1
(43) Pub. Date: Jul. 30, 2026

(54) SIDE-BY-SIDE INTEGRATED DEVICE PACKAGE WITH WIREBOND INTERCONNECTS

(71) Applicant: QUALCOMM Incorporated, San Diego, CA (US)

(72) Inventors: Aniket PATIL, San Diego, CA (US); Joan Rey Villarba BUOT, Escondido, CA (US); Zhijie WANG, San Diego, CA (US)

(21) Appl. No.: 19/039,203

(22) Filed: Jan. 28, 2025

(51) Int. Cl. H01L 25/16; H01L 21/48; H01L 21/56; H01L 23/00; H01L 23/13; H01L 23/31; H01L 23/498; H10B 80/00; H10D 80/30

(52) U.S. Cl. CPC H10W 90/00; H10B 80/00; H10D 80/30; H10W 70/093; H10W 70/68; H10W 74/016; H10W 74/019; H10W 74/117; H10W 90/401; H10W 90/701; H10W 72/07232; H10W 72/07236; H10W 90/724; H10W 90/794

(57) ABSTRACT

A device that includes a first substrate that includes a first set of conductors. The first set of conductors define first contacts for a first die and first conductive interconnects to route signals associated with the first die. The device includes a second substrate that includes a second set of conductors. The second set of conductors define second contacts for a second die and second conductive interconnects to route signals associated with the second die. The device includes a set of wirebond interconnects electrically coupled to the first set of conductors and the second set of conductors. The device includes mold compound that at least partially encapsulates the first substrate, the second substrate, and the set of wirebond interconnects. The mold compound is configured to retain the first substrate and the second substrate in position relative to one another in a side-by-side configuration.

### FIELD

Various features relate to integrated device packages.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

State-of-the-art electronic devices generally demand a small form factor, low cost, a tight power budget, and high electrical performance. Integrated device package design has evolved in an attempt to meet these various goals; however, these goals are often in conflict with one another. For example, smaller integrated device packages may be more expensive to manufacture and provide less space for routing conductive paths between dies and/or other components of the integrated device package, which can limit electrical performance. One approach to address many of these goals is to use a package-on-package (PoP) configuration; however, PoP configurations can introduce other concerns, such as heat management. Due in part to heat management concerns, designers of high-end electronic devices may prefer side-by-side configurations. However, interconnecting two high-end dies together in a side-by-side configuration on a package substrate requires a large number of conductive paths, which increases the cost and size of the package substrate.

### SUMMARY

Various features relate to integrated circuit devices.

One example provides a device that includes a first substrate that includes a first set of conductors. The first set of conductors define first contacts for a first die and first conductive interconnects to route signals associated with the first die. The device also includes a second substrate that includes a second set of conductors. The second set of conductors define second contacts for a second die and second conductive interconnects to route signals associated with the second die. The device also includes a set of wirebond interconnects electrically coupled to the first set of conductors and the second set of conductors. The device further includes mold compound that at least partially encapsulates the first substrate, the second substrate, and the set of wirebond interconnects. The mold compound is configured to retain the first substrate and the second substrate in position relative to one another in a side-by-side configuration.

Another example provides a method of fabrication that includes arranging a first substrate and a second substrate side-by-side on a carrier. The first substrate includes a first set of conductors that define first contacts for a first die and first conductive interconnects to route signals associated with the first die, and the second substrate includes a second set of conductors that define second contacts for a second die and second conductive interconnects to route signals associated with the second die. The method also includes electrically coupling a set of wirebond interconnects between the first set of conductors and the second set of conductors. The method further includes applying a mold compound to at least partially encapsulate the first substrate, the second substrate, and the set of wirebond interconnects to retain the first substrate and the second substrate in position relative to one another in a side-by-side configuration.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a schematic cross-sectional profile view of an exemplary side-by-side integrated device package with wirebond interconnects.

FIG. 2 illustrates a schematic cross-sectional profile view of another exemplary side-by-side integrated device package with wirebond interconnects.

FIG. 3 illustrates a schematic cross-sectional profile view of another exemplary side-by-side integrated device package with wirebond interconnects.

FIG. 4A illustrates a first part of an exemplary sequence for fabricating an exemplary side-by-side integrated device package with wirebond interconnects.

FIG. 4B illustrates a second part of an exemplary sequence for fabricating an exemplary side-by-side integrated device package with wirebond interconnects.

FIG. 4C illustrates a third part of an exemplary sequence for fabricating an exemplary side-by-side integrated device package with wirebond interconnects.

FIG. 4D illustrates a second part of an alternative exemplary sequence for fabricating an exemplary side-by-side integrated device package with wirebond interconnects.

FIG. 5 illustrates an exemplary flow diagram of a method of semiconductor fabrication for a side-by-side integrated device package with wirebond interconnects.

FIG. 6 illustrates various electronic devices that may integrate an exemplary side-by-side integrated device package with wirebond interconnects described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple metal layers are illustrated and associated with reference numbers 114A, 114B, and 114C. When referring to a particular one of these metal layers, such as a metal layer 114A, the distinguishing letter “A” is used. However, when referring to any arbitrary one of these metal layers or to these metal layers as a group, the reference number 114 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

Improvements in manufacturing technology and demand for lower cost and more capable electronic devices has led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art device.

These interconnections include back-end-of-line (BEOL) interconnect layers, which may refer to the conductive interconnect layers for electrically coupling to front end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middleof-line (MOL) interconnect layers, which interconnect to the FEOL active devices of an IC.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

Aspects of the present disclosure are directed to side-by-side integrated device packages with wirebond interconnects. In some circumstances, side-by-side packages may be preferred over PoP packages, such as to reduce heat management concerns. However, side-by-side package substrates can be expensive to fabricate. For example, a typical side-by-side package may include one or more memory dies (e.g., double data rate (DDR) dynamic random access memory (DRAM) dies) coupled to a system-on-chip (SOC) die with one or more processor cores and other circuitry. Under an exemplary set of design rules, a laminate package substrate used to provide DDR connections to a DRAM uses six metal layers in order to provide power, ground, off-package connections, and adequate isolation between signal paths. The number of metal layers needed can be reduced by using redistribution layer (RDL) materials and techniques instead of or in addition to using lamination materials and techniques; however, RDL fabrication is generally much more expensive than laminate substrate manufacturing.

Further, when multiple dies are interconnected in a side-by-side configuration, the different dies may have different interconnection constraints. In this situation, if a single large side-by-side package substrate is used for the entire device package, the die subject to the most demanding constraints drives the design of the package substrate, which increases cost and size of the package substrate. To illustrate, power and signal paths for a first die may be routable using only three metal layers (e.g., a first metal layer for interconnection, a second metal layer for isolation, and a third metal layer for off-package contacts); whereas routing power and signal paths for a second die may need more than three metal layers, e.g., six metal layers. In this situation, a package substrate to route connections for both of these dies would need to include six metal layers in order to accommodate the second die, leading to a larger (e.g., thicker) and more expensive package substrate.

Particular examples disclosed herein address some or all of these concerns, by using different package substrates for different dies. For example, a particular device (e.g., an integrated device package) can include a first substrate and a second substrate. In this example, the first substrate can include a first set of conductors that define first contacts for a first die and first conductive interconnects to route signals associated with the first die, and the second substrate can include a second set of conductors that define second contacts for a second die and second conductive interconnects to route signals associated with the second die. The first and second substrates can be electrically coupled to one another by a set of wirebond interconnects. The device can also include mold compound that at least partially encapsulates the first substrate, the second substrate, and the set of wirebond interconnects to retain the first substrate and the second substrate in position relative to one another in a side-by-side configuration. Optionally, the device can also include a support structure coupled to the first substrate and the second substrate to provide additional mechanical stability.

Using different package substrates for dies with different signal routing requirements enables the layer count of each package substrate to be limited by the corresponding die rather than the most limiting die of the integrated device package. Further, different materials and fabrication techniques can be used for different package substrates. To illustrate, in the example above, less expensive laminate materials and fabrication techniques can be used for the first substrate, and more expensive RDL materials and fabrication techniques can be used for the second substrate. Using different package substrates, which optionally can be formed using different materials and/or different fabrication techniques, offers several technical advantages. For example, the different package substrates can each be limited by routing constraints associated with dies attached thereto, which improves design flexibility for each package substrate and can reduce overall package cost. Additionally, the individual package substrates can be redesigned or modified separately, such as due to updated constraints or use of different dies, which improves design and manufacturing flexibility. Using different package substrates for dies having different routing constraints can also enable package designers to mix more expensive and less expensive materials and fabrication techniques within a single integrated device package to address cost goals and package size goals at the same time. For example, consider an integrated device package that is to include a first die and a second die with different routing constraints (e.g., the second die's routing constraints are more limiting than the first die's routing constraints). In this example, a first package substrate for the first die may be formed using lamination techniques, and a second package substrate for the second die may be formed using RDL techniques. In this example, the first package substrate is likely to be thicker but less expensive than the second package substrate. However, the use of RDL techniques to form the second package substrate may enable the second die's routing constraints to be satisfied by a thinner package substrate than if the second package substrate were formed using lamination techniques. Thus, the overall dimensions of the integrated device package (including the first and second package substrates) are less than the overall dimensions of an integrated device package that includes a single laminate package substrate coupled to both the first and second dies. Likewise, the combined cost of fabricating the first and second package substrates is less than the cost of fabricating a single RDL-based package substrate coupled to both the first and second dies.

### Exemplary Devices Including Side-by-Side Integrated Device Package with Wirebond Interconnects

FIGS. 1-3 illustrate various examples of side-by-side integrated device packages with wirebond interconnects between package substrates. The various examples shown in FIGS. 1-3 highlight particular non-limiting aspects of integrated device packages according to the present disclosure.

In the example of FIG. 1, an integrated device package 100 includes a package substrate 102 (e.g., a first package substrate) and a package substrate 112 (e.g., a second package substrate). The package substrates 102, 112 are electrically coupled to one another by wirebond interconnects 134. The wirebond interconnects 134 form part of the signal paths between one or more dies (e.g., a die 108) electrically coupled to the package substrate 102 and one or more dies (e.g., a die 140) electrically coupled to the package substrate 112.

The package substrate 102 includes a set of metal layers 104 (e.g., metal layers 104A, 104B, and 104C) that are separated from one another by dielectric layers 106 and that are patterned and interconnected to form conductors (e.g., contacts, lines, and vias). The conductors of the package substrate 102 are configured according to a set of routing constraints that are associated with a die 108 (e.g., a first die) and with materials and fabrication techniques used to form the package substrate 102. For example, the metal layer 104A of the substrate 102 defines a set of contacts 110 corresponding to contacts of the die 108 and contacts for the wirebond interconnects 134. Further, the metal layer 104C defines a set of off-package contacts 136 configured to couple, via off-package interconnects 142 (e.g., solder balls or solder bumps), to a printed circuit board, another electrical interconnection, and/or one or more other devices (e.g., other discrete components, other integrated device packages, etc.). In this example, the metal layer 104B is configured to route signals, power, and ground between and among respective pairs or sets of the contacts 110 and the off-package contacts 136.

Similarly, the package substrate 112 includes a set of metal layers 114 (e.g., metal layers 114A, 114B, and 114C) that are separated from one another by dielectric layers 116 and that are patterned and interconnected to form conductors (e.g., contacts, lines, and vias). The conductors of the package substrate 112 are configured according to a set of routing constraints that are associated with a die 140 (e.g., a second die) and with materials and fabrication techniques used to form the package substrate 112. For example, the metal layer 114A of the substrate 112 defines a set of contacts 120 corresponding to contacts of the die 140 and contacts for the wirebond interconnects 134. Further, the metal layer 114C defines a set of off-package contacts 138 configured to couple, via the off-package interconnects 142, to a printed circuit board, another electrical interconnection, and/or one or more other devices (e.g., other discrete components, other integrated device packages, etc.). In this example, the metal layer 114B is configured to route signals, power, and ground between and among respective pairs or sets of the contacts 120 and the off-package contacts 138.

The integrated device package 100 of FIG. 1 includes mold compound 130 that at least partially encapsulates the package substrate 102, the package substrate 112, and the wirebond interconnects 134. The mold compound 130 is configured to retain the package substrate 102 and the package substrate 112 in position relative to one another in a side-by-side configuration. For example, the mold compound 130 resists warpage of the integrated device package 100 and helps to maintain a bottom surface of the package substrate 102 substantially co-planar with a bottom surface of the package substrate 112.

In some embodiments, the integrated device package 100 also includes one or more support structures, such as support structure 132, that provide additional mechanical reinforcement to support the package substrates 102, 112 and/or to resist warpage of the integrated device package 100. In the example illustrated in FIG. 1, the support structure 132 corresponds to or includes a rigid ring around the bottom surface of the integrated device package 100. In other examples, the support structure(s) 132 can have other physical configurations, such as rods, pins, or rails that extend between the package substrates 102, 112. The support structure(s) 132 are optional and are omitted in some embodiments.

In the example illustrated in FIG. 1, a single intermediate metal layer (e.g., metal layer 104B) is disposed between a top metal layer (e.g., metal layer 104A) and a bottom metal layer (e.g., metal layer 104C) of the package substrate 102; however, in other examples, the package substrate 102 can include more than one intermediate metal layer. For example, the package substrate 102 can include as many intermediate metal layers as are needed to route signals, power, and ground between the die 108 and the wirebond interconnects 134 and off-package contacts 136 of the package substrate 102 based on the routing constraints associated with the package substrate 102. The routing constraints can depend on materials and fabrication techniques used to form the package substrate 102, characteristics of the die 108, industry or company standard design considerations, etc. To illustrate, the routing constraints may be based on line width and line spacing of conductive lines of the metal layers 104 associated with materials and fabrication techniques used to form the package substrate 102, line separation selected to maintain signal integrity for various signals routed to or from the die 108, a contact configuration of the die 108, etc.

Likewise, although the package substrate 112 is illustrated in FIG. 1 with a single intermediate metal layer (e.g., metal layer 114B) disposed between a top metal layer (e.g., metal layer 114A) and a bottom metal layer (e.g., metal layer 114C) of the package substrate 112, in other examples, the package substrate 112 can include more than one intermediate metal layer. For example, the package substrate 112 can include as many intermediate metal layers as are needed to route signals, power, and ground between the die 140 and the wirebond interconnects 134 and off-package contacts 138 of the package substrate 112 based on the routing constraints associated with the package substrate 112.

The package substrates 102, 112 can have different dimensions (e.g., different thicknesses, different widths, different shapes, etc.) than one another. For example, in FIG. 1, the package substrate 102 is shown as having a different (e.g., greater) thickness than the package substrate 112. In this example, the difference in thickness can be due to differences in the thickness or count of metal layers 104 as compared to the thickness or count of metal layers 114, differences in the thickness or count of dielectric layers 106 as compared to the thickness or count of dielectric layers 116, or both. As one illustrative example, the package substrate 102 can be formed using lamination techniques, and the package substrate 112 can be formed using redistribution layer fabrication techniques. In this illustrative example, the package substrate 102 includes a metal-prepreg composite stack, in which the dielectric layers 106 include fiber-reinforced polymer layers. In contrast, in this illustrative example, the package substrate 112 includes a set of redistribution layers, in which the dielectric layers 116 include unreinforced polymer layers. Further, as in this illustrative example, the metal layers 114 are each thinner than the metal layers 104, as is typical for redistribution layers as compared to laminated metal-prepreg composite stacks.

Due to the different materials and/or fabrication techniques used to form the package substrates 102, 112, the package substrates 102, 112 can have different thicknesses even if the count of metal layers 104, 114 of the package substrates 102, 112 are equal to one another. For example, the package substrate 102 has a first count of the metal layers 104 (e.g., three in FIG. 1), and the package substrate 112 has a second count of the metal layers 114 (e.g., three in FIG. 1) that is equal to the first count; nevertheless, the package substrates 102, 112 have different thicknesses due to the different materials and/or fabrication techniques used to form them. The materials and fabrication techniques used to form each package substrates 102, 112 can also influence other characteristics of the package substrates 102, 112. For example, differences between the materials and fabrication techniques used to form redistribution layers as compared to laminated metal-prep stacks can enable the redistribution layers to have comparatively finer line width and finer pitch between lines and/or contacts, which enables higher density routing of signal paths.

Each of the dies 108, 140 can include various circuits. For example, each of the dies 108, 140 can include integrated circuitry, such as a plurality of transistors and/or other circuit elements arranged and interconnected to form logic cells, memory cells, filters, amplifiers, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, a front end-of-line (FEOL) process may be used to fabricate the integrated circuitry in and/or over the semiconductor substrate. As non-limiting examples, the die 108, the die 140, or both, can include one or more of a power management integrated circuit (PMIC), an application processor, a modem, a radio frequency (RF) device, a passive device, a filter, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory circuit, a power management processor, and/or combinations thereof. In additional non-limiting examples, the die 108, the die 140, or both, can include one or more microcontrollers, application specific integrated circuits (ASICs), field programmable gate arrays (FPGAs), central processing units (CPUs) having one or more processing cores, processing systems, system on chip (SoC), or other circuitry and logic configured to facilitate the operations of the dies 108, 140. Additionally, or alternatively, one or both of the dies 108, 140 may include or be operated as a memory, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof

In addition to active circuits, one or both of the dies 108, 140 can include various passive components, such as capacitors, inductors, or resistors. Further, while each die 108, 140 is illustrated as a single monolithic device in FIG. 1, in other embodiments, the die 108, the die 140, or both, can include or be replaced with a stacked integrated circuit device, e.g., a stack of chiplets. For example, the die 108, the die 140, or both, may include or correspond to a three-dimensional (3D) integrated circuit (IC) device.

In one non-limiting example, the die 108 includes one or more processor cores, and the die 140 includes one or more memory cells accessible to the one or more processor cores via the set of wirebond interconnects 134. To illustrate, in this example, the contacts 120 of the substrate 112 can be arranged according to a Joint Electron Device Engineering Council (JEDEC) Solid State Technology Association specification for double data rate (DDR) dynamic random access memory (DRAM) interconnection. As noted above, using conventional lamination techniques and materials, routing signal, power, and ground for a DDR DRAM (e.g., the die 140) in the substrate 112 would typically require six metal layers; however, by using redistribution layer fabrication techniques to form the substrate 112, the substrate 112 can be formed to route signal, power, and ground paths in as few as three metal layers (e.g., due to higher density routing of signal paths, as described above). As a result, overall dimensions (e.g., thickness) of the integrated device package 100 can be reduced relative to a device package that uses a single monolithic laminate package substrate for both dies 108 and 140. Furthermore, fabrication of the substrate 112 is considerably less expensive than would be fabrication of a single monolithic redistribution layer-based package substrate for both die 108 and 140.

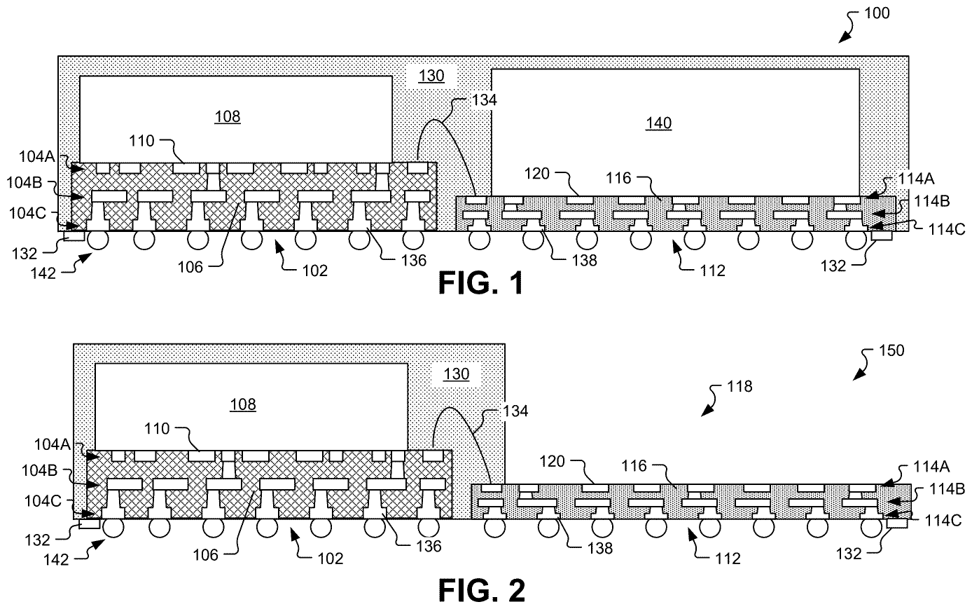

FIG. 2 illustrates an example of an integrated device package 150 that includes many of the same features as the integrated device package 100 of FIG. 1. For example, the integrated device package 150 includes the die 108 electrically coupled to the package substrate 102. The integrated device package 150 also includes the package substrate 112 and the wirebond interconnects 134 electrically coupling the package substrates 102, 112.

In the example illustrated in FIG. 2, the die 140 and a portion of the mold compound 130 are omitted to define a region 118 configured to receive the die 140 at a later time. To illustrate, a first manufacturer may fabricate the integrated device package 150 of FIG. 2, and a second manufacturer may subsequently electrically couple the die 140 to the integrated device package 150 to form the integrated device package 100. In this illustrative example, the second manufacturer can optionally add additional mold compound 130 to at least partially encapsulate the die 140 after it is electrically coupled to the package substrate 112.

As one non-limiting example, the contacts 120 of the package substrate 112 can be arranged according to a standard configuration, such as the JEDEC Solid State Technology Association specification for DDR DRAM interconnection. In this example, the die 140 can include a set of pins or contacts that are also arranged according to the standard configuration (e.g., the die 140 can include a JEDEC-compliant DRAM die). In this example, the first manufacture can fabricate the integrated device package 150, including components such as the die 108 and/or other components including one or more processor cores and provide the integrated device package 150 to the second manufacturer for completion with a JEDEC-compliant DRAM die selected by the second manufacturer.

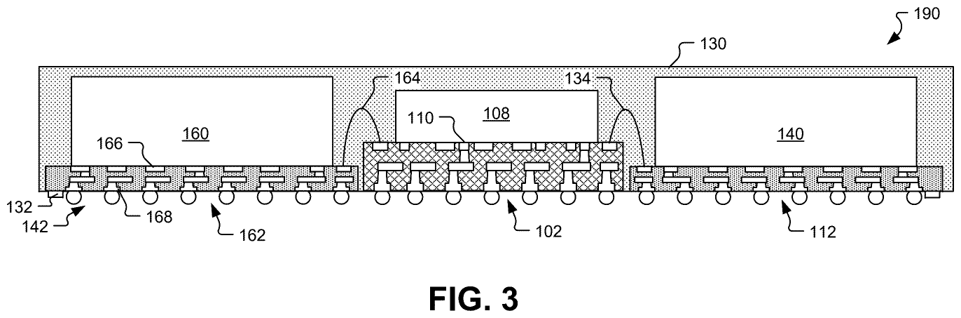

FIG. 3 illustrates an example of an integrated device package 190 that includes all of the same features as the integrated device package 100 of FIG. 1 and also includes one or more additional package substrates. For example, in FIG. 3, the integrated device package 190 includes the package substrate 102, the package substrate 112, and a package substrate 162.

The package substrate 162 has similar features to the package substrates 102, 112. For example, the package substrate 162 includes a plurality of metal layers that are separated from one another by dielectric layers and that are patterned to define conductors to route signals, power, and ground. To illustrate, the metal layers define contacts 166 of the package substrate 162 that are configured to electrically couple a die 160 to the package substrate 162. The metal layers also define or are electrically coupled to off-package contacts 168 of the package substrate 162.

A count of metal layers of the package substrate 162 is based on routing constraints associated with the package substrate 162, as previously described. Thus, the package substrate 162 can include the same count of metal layers as either or both of the package substrates 102, 112, or the package substrate 162 can include a different count of metal layers than either of the package substrates 102, 112. Further, the package substrate 162 can be fabricated using the same materials and/or techniques as either or both of the package substrates 102, 112, or the package substrate 162 can be fabricated using different materials and/or techniques than both of the of the package substrates 102, 112.

A set of the contacts 166 are electrically coupled to wirebond interconnects 164, which are also electrically coupled to a set of the contacts 110 of the package substrate 102. Thus, the wirebond interconnects 164 form portions of conductive paths between the package substrates 102, 162 to enable routing of signals between the dies 108 and 160.

The mold compound 130 of the integrated device package 190 at least partially encapsulates the package substrate 162 and the wirebond interconnects 164. Optionally, the mold compound 130 can also at least partially encapsulate the die 160. Alternatively, the die 160 and a portion of the mold compound 130 shown in FIG. 3 can be omitted to expose the contacts 166 for later attachment of the die 160.

Although FIG. 3 illustrates an example of the integrated device package 190 with three package substrates 102, 112, 162 interconnected by two sets of wirebond interconnects 134, 164, in other examples, the integrated device package 190 can include more than three package substrates, in which case additional sets of wirebond interconnects can be used to electrically couple the package substrates to one another in various combinations. Further, although the three package substrates 102, 112, 162 shown in FIG. 3 are arranged in a row or line, in other embodiments, three or more package substrates can be arranged and electrically interconnected in a different geometry. For example, the three package substrates 102, 112, 162 of FIG. 3 can be arranged in a triangular configuration in which case, in addition to being electrically coupled to the package substrate 102 by the wirebond interconnects 134, 164, the package substrate 112 and the package substrate 162 may be electrically coupled to one another by one or more additional sets of wirebond interconnects.

In a particular implementation, each of the integrated device packages 100, 150, 190 includes a first substrate (e.g., the package substrate 102) including a first set of conductors (e.g., the metal layers 104) that define first contacts (e.g., the contacts 110) for a first die (e.g., the die 108) and first conductive interconnects (e.g., lines and vias of the metal lines 104) to route signals associated with the first die. Each of the integrated device packages 100, 150, 190 also includes a second substrate (e.g., the package substrate 112) including a second set of conductors (e.g., the metal layers 114) that define second contacts (e.g., the contacts 120) for a second die (e.g., the die 140) and second conductive interconnects (e.g., lines and vias of the metal layers 114) to route signals associated with the second die. Each of the integrated device packages 100, 150, 190 further includes a set of wirebond interconnects (e.g., the wirebond interconnects 134) electrically coupled to the first set of conductors and the second set of conductors. Each of the integrated device packages 100, 150, 190 also includes mold compound (e.g., mold compound 130) that at least partially encapsulates the first substrate, the second substrate, and the set of wirebond interconnects, where the mold compound is configured to retain the first substrate and the second substrate in position relative to one another in a side-by-side configuration.

### Exemplary Sequence for Fabricating a Side-by-side Integrated Device Package with Wirebond Interconnects

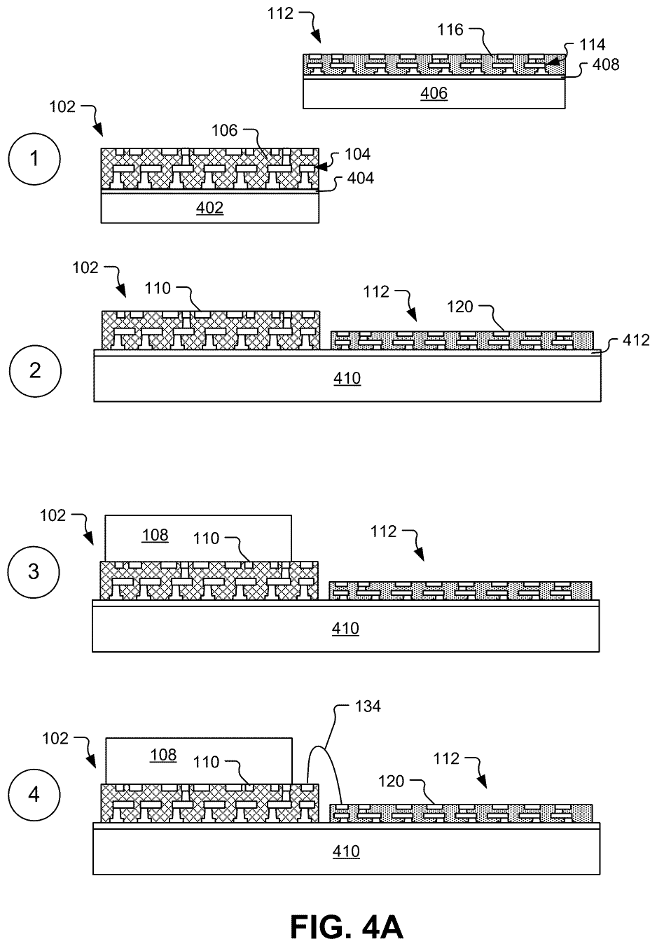

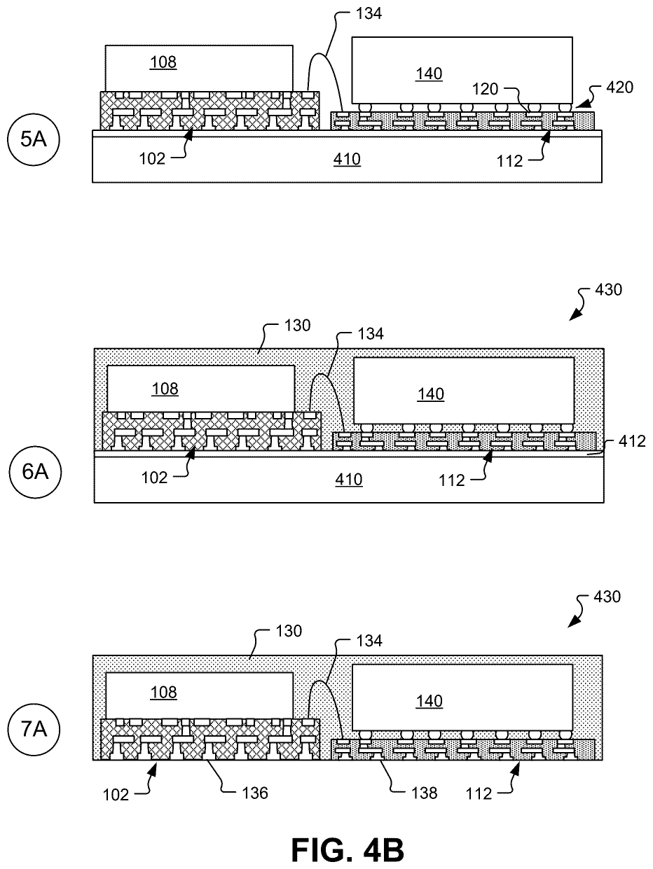

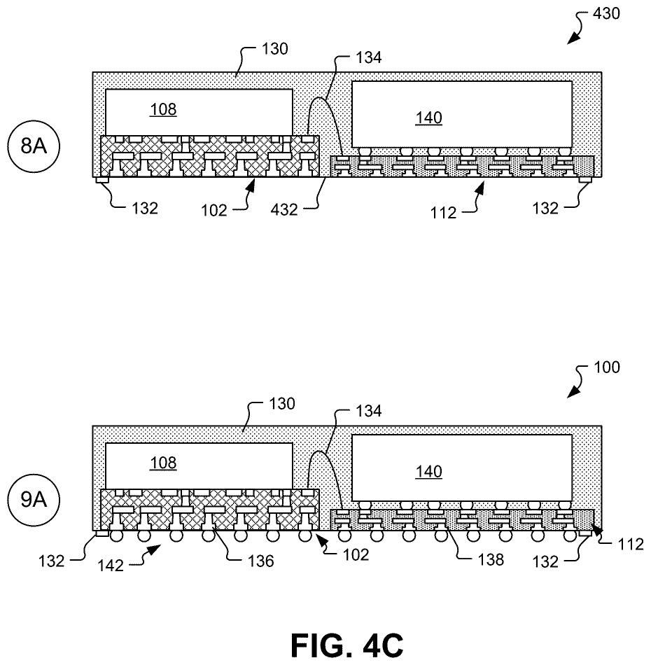

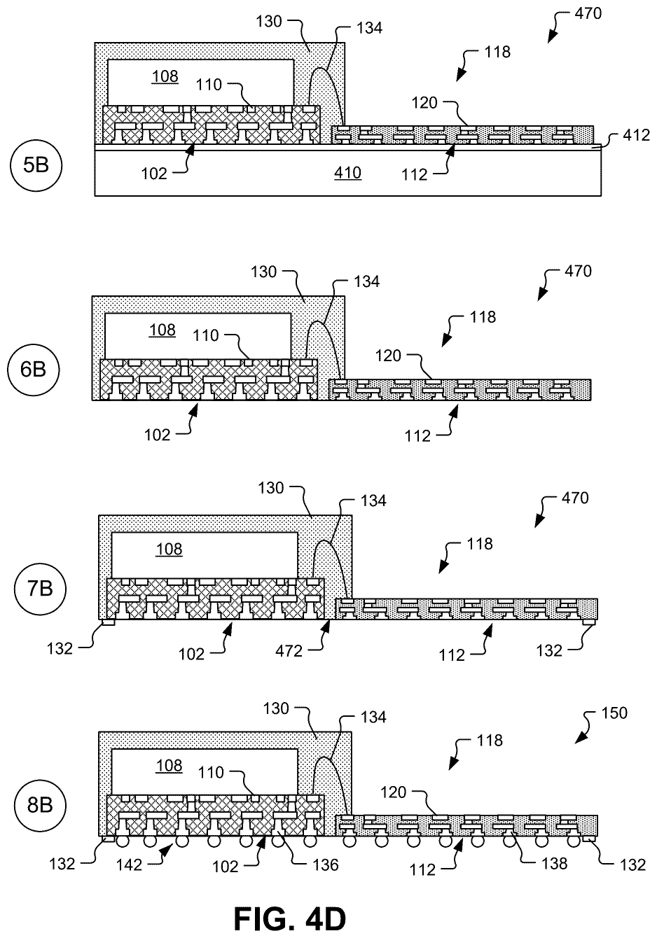

In some implementations, fabricating a side-by-side integrated device package with wirebond interconnects (e.g., any of the device packages 100, 150, 190 of FIGS. 1-3) includes several processes. FIGS. 4A-D illustrate several exemplary sequences for fabricating or providing side-by-side integrated device packages with wirebond interconnects, as described with reference to any of FIGS. 1-3. In some implementations, the sequence described with reference to FIGS. 4A, 4B and 4C may be used to provide (e.g., during fabrication of) one or more of the integrated device package 100 of FIG. 1 or the integrated device package 190 of FIG. 3. In some implementations, the sequence described with reference to FIGS. 4A and 4D may be used to provide (e.g., during fabrication of) the integrated device package 150 of FIG. 2.

It should be noted that the sequence of FIGS. 4A-D may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence. The various Stages are distinguished using circled numbers in FIG. 4A, and using circled numbers followed by letters in FIGS. 4B-4D, where the letters indicate different options. For example, Stages associated with a letter “A” are associated with fabrication of an integrated device package in which each package substrate is electrically coupled to at least one die, such as the integrated device package 100 or the integrated device package 190. In contrast, Stages associated with a letter “B” are associated with fabrication of an integrated device package in which contacts of at least one package substrate are left exposed for later attachment to a die, such as the integrated device package 150 of FIG. 2. Each of the various Stages of the sequences illustrated in FIGS. 4A-D shows a single integrated device package being formed. In other implementations, multiple integrated device packages may be formed concurrently, e.g., using strip level or panel level operations.

Stage 1 of FIG. 4A illustrates a state after formation of the package substrate 102 and the package substrate 112. For example, as part of Stage 1, the metal layers 104 and the dielectric layers 106 of the package substrate 102 are formed on a carrier 402, and the metal layers 114 and the dielectric layers 116 of the package substrate 112 are formed on a carrier 406. In the particular example illustrated, a release layer 404 is disposed between the package substrate 102 and the carrier 402, and a release layer 408 is disposed between the package substrate 112 and the carrier 406.

In some embodiments, the package substrates 102, 112 are formed using the same (or similar) materials and fabrication techniques. For example, each of the package substrates 102, 112 can be formed using lamination techniques, such as arranging fiber-reinforced polymer materials (e.g., prepreg materials) and patterned metal foil layers to form laminate-based substrates. A metal foil layer can be patterned before it is applied or after it is applied to a prepreg layer.

As another example, one or both of the package substrates 102, 112 can be formed using redistribution layer fabrication techniques, such as depositing unreinforced polymer materials to form one of the dielectric layers and depositing a metal layer on the dielectric layer. In this example, the unreinforced polymer materials can be deposited as a dry film or as a liquid or gel, and the metal layers can be deposited using plating, spraying, vapor deposition, or other similar techniques used to form thin metal layers.

The package substrates 102, 112 can have the same count of metal layers 104, 114, or different counts of metal layers 104, 114. Further, the package substrates 102, 112 can be formed concurrently or separately. In some embodiments, the package substrate 102 can be formed at a different location than the package substrate 112, such as by a different manufacturer or at a different manufacturing facility. For example, redistribution layer fabrication techniques and laminate fabrication techniques use different tools sets and different manufacturing environments. Thus, if the package substrate 102 is formed using laminate fabrication techniques and the package substrate 112 is formed using redistribution layer fabrication techniques, the package substrates 102, 112 can be formed at different facilities or in different manufacturing lines.

Stage 2 illustrates a state after the package substrates 102, 112 are separated from their respective carriers 402, 406 and attached to a carrier 410 via an adhesive layer 412. Stage 3 illustrates a state after a die 108 is electrically coupled to contacts 110 of the package substrate 102. For example, the die 108 can be coupled to the package substrate 102 using flip-chip die attach techniques, such as solder reflow or thermo-compression bonding.

Stage 4 illustrates a state after wirebond interconnects 134 are formed to attach conductors of the package substrate 102 and the package substrate 112. For example, the wirebond interconnects 134 can be formed using a wire bonder to solder ends of a wire to respective contacts of the package substrates 102, 112.

Stage 5A of FIG. 4B illustrates a state after the die 140 is electrically coupled to the package substrate 112. For example, the die 140 can be coupled to the package substrate 112 using flip-chip die attach techniques, such as solder reflow or thermo-compression bonding. In the example illustrated in FIG. 4B, the die 140 includes solder bumps 420 that are reflowed to attach the die 140 to contacts 120 of the package substrate 112.

The order of the operations described with reference to Stages 3, 4, and 5A of FIGS. 4A and 4B is merely one example. In other examples, the operations described with reference to Stages 3, 4, and 5A are performed in a different order. For example, in some cases, the dies 108, 140 can be attached to their respective package substrates 102, 112 before the wirebond interconnects 134 are formed. As another example, in some cases, the wirebond interconnects 134 can be formed before either of the dies 108, 140 are attached.

Stage 6A illustrates a state after application of the mold compound 130 to form an assembly 430 coupled to the carrier 410. The mold compound 130 at least partially encapsulates the package substrates 102, 112, the wirebond interconnects 134, and the dies 108, 140. In a particular example, overmolding operations are used to apply the mold compound 130 to form the assembly 430. Stage 7A illustrates a state after the assembly 430 is detached from the carrier 410. If Stages 1-6A have been performed to form multiple assemblies 430 concurrently (e.g., using strip-level or panel-level operations), the assemblies 430 can be individuated at Stage 7A.

Stage 8A of FIG. 4C illustrates a state after one or more support structures 132 are coupled to a bottom surface 432 of the assembly 430. For example, the support structure(s) 132 can include one or more rigid structures, such as a ring, rods, pins, or rails configured to resist warpage of the assembly 430, misalignment (e.g., non-coplanarity) of bottom surfaces of the package substrates 102, 112, separation of the package substrates 102, 112, etc. In particular examples, the support structure(s) 132 include metal (or metal alloys), a ceramic, or a fiber reinforced polymer. The support structure(s) 132 can be coupled to the bottom surface 432 of the assembly 430 using an adhesive.

Stage 9A illustrates a state after the off-package interconnects 142 are coupled to the off-package contacts 136 of the package substrate 102 and to the off-package contacts 138 of the package substrate 112 to form the integrated device package 100. Formation of the integrated device package 100 is complete after Stage 9A of FIG. 4C.

In examples in which the operations described with reference to Stages 1-9A are used to fabricate an integrated device package that includes more than two package substrates (e.g., the integrated device package 190 of FIG. 3), appropriate ones of Stages 1-9A are repeated or replicated concurrently for the additional package substrates. For example, during fabrication of the integrated device package 190 of FIG. 3, three package substrates (e.g., the package substrates 102, 112, and 162) are formed at Stage 1 and are attached to the carrier 410 at Stage 2. Further, in this example, the wirebond interconnects 164 of FIG. 3 can be formed at Stage 4 of FIG. 4A using similar techniques described there.

In some embodiments, during fabrication of an integrated device package, like the integrated device package 150 of FIG. 2, in which at least one region 118 is formed for later attachment of a die, Stages 5A-9A are omitted, and Stage 5B of FIG. 4D follows Stage 4 of FIG. 4A. In such embodiments, Stage 5B illustrates a state after application of the mold compound 130 to form an assembly 470 coupled to the carrier 410. The mold compound 130 is selectively applied such that a set of the contacts 120 of the package substrate 112 are not covered by the mold compound 130. For example, the mold compound 130 at least partially encapsulates the package substrates 102, 112, the wirebond interconnects 134, and the die 108 and leaves the set of the contacts 120 exposed in the region 118. In a particular example, overmolding operations are used to apply the mold compound 130 to form the assembly 470.

Stage 6B illustrates a state after the assembly 470 is detached from the carrier 410. If Stages 1-4 and 5B have been performed to form multiple assemblies 470 concurrently (e.g., using strip-level or panel-level operations), the assemblies 470 can be individuated at Stage 6B.

Stage 7B illustrates a state after one or more support structures 132 are coupled to a bottom surface 472 of the assembly 470. For example, the support structure(s) 132 can include one or more rigid structures, such as a ring, rods, pins, or rails configured to resist warpage of the assembly 470, misalignment (e.g., non-coplanarity) of bottom surfaces of the package substrates 102, 112, separation of the package substrates 102, 112, etc. In particular examples, the support structure(s) 132 include metal (or metal alloys), a ceramic, or a fiber reinforce polymer. The support structure(s) 132 can be coupled to the bottom surface 472 of the assembly 470 using an adhesive.

Stage 8B illustrates a state after the off-package interconnects 142 are coupled to the off-package contacts 136 of the package substrate 102 and to the off-package contacts 138 of the package substrate 112 to form the integrated device package 150. Formation of the integrated device package 150 is complete after Stage 8B of FIG. 4D; however, additional operations may subsequently be performed to attach a die to exposed contacts 120 within the region 118. For example, die attach operations, such as solder reflow or thermo-compression bonding, can be used to attach a die to the contacts 120 in the region 118, and optionally, overmolding operations can be used to add additional mold compound to at least partially encapsulate the die attached in the region 118.

In examples in which the operations described with reference to Stages 1-4 and 5B-8B are used to fabricate an integrated device package that includes more than two package substrates (e.g., the integrated device package 190 of FIG. 3) with at least one region 118 left for attachment of additional die(s), appropriate ones of Stages 1-4 and 5B-8B are repeated or replicated concurrently for the additional package substrates, as described above with reference to fabrication of the integrated device package 190 of FIG. 3.

### Exemplary Flow Diagram of a Method for Fabricating a Side-by-side Integrated Device Package With Wirebond Interconnects

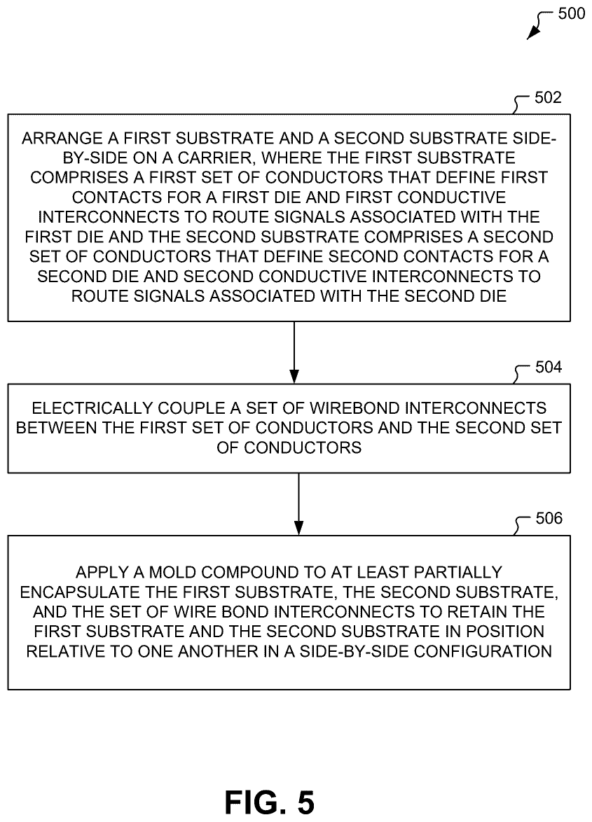

In some implementations, fabricating a side-by-side integrated device package with wirebond interconnects includes several processes. FIG. 5 illustrates an exemplary flow diagram of a method 500 of fabricating an illustrative side-by-side integrated device package with wirebond interconnects. In a particular aspect, one or more operations of the method 500 are initiated, performed, or controlled by one or more processors of a fabrication system. In some implementations, operations of the method 500 may be stored as instructions by a non-transitory computer-readable storage medium, and the instructions may be executable by at least one processor to cause the at least one processor to perform operations of the method 500. In some implementations, the method 500 of FIG. 5 may be used to provide or fabricate any of the integrated device packages 100, 150, or 190 of FIGS. 1-3, 4C, or 4D.

It should be noted that the method 500 of FIG. 5 may combine one or more processes in order to simplify and/or clarify the method for providing or fabricating an integrated device package. In some implementations, the order of the processes may be changed or modified.

The method 500 includes, at block 502, arranging a first substrate and a second substrate side-by-side on a carrier. For example, Stage 2 of FIG. 4A illustrates and describes an example of arranging a first substrate (e.g., the package substrate 102) and a second substrate (e.g., the package substrate 112) side-by-side on the carrier 410. In the example of the method 500, the first substrate includes a first set of conductors that define first contacts (e.g., the contacts 110 of FIG. 1) for a first die (e.g., the die 108) and first conductive interconnects (e.g., lines and vias of the metal layers 104) to route signals associated with the first die. Further, in this example, the second substrate includes a second set of conductors that define second contacts (e.g., the contacts 120) for a second die (e.g., the die 140) and second conductive interconnects (e.g., lines and vias of the metal layers 114) to route signals associated with the second die.

The method 500 also includes, at block 504, electrically coupling a set of wirebond interconnects between the first set of conductors and the second set of conductors. For example, Stage 4 of FIG. 4A illustrates and describes operations to electrically couple a set of wirebond interconnects (e.g., the wirebond interconnects 134) between the first set of conductors (e.g., the contacts 110 defined by the metal layers 104) and the second set of conductors (e.g., the contacts 120 defined by the metal layers 114).

The method 500 also includes, at block 506, applying a mold compound to at least partially encapsulate the first substrate, the second substrate, and the set of wirebond interconnects to retain the first substrate and the second substrate in position relative to one another in a side-by-side configuration. For example, Stage 6A of FIG. 4B and Stage 5B of FIG. 4D illustrate and describe operations to apply the mold compound 130.

In a particular example, the method 500 includes electrically coupling the first die, the second die, or both, to respective substrates before applying the mold compound. For example, the first die (e.g., the die 108) can be electrically coupled to the first contacts (e.g., the contacts 110) of the first substrate (e.g., the package substrate 102) before the mold compound (e.g., the mold compound 130) is applied, in which case the mold compound at least partially encapsulates the first die. Additionally, or alternatively, the second die (e.g., the die 140) can be electrically coupled to the second contacts (e.g., the contacts 120) of the second substrate (e.g., the package substrate 112) before the mold compound (e.g., the mold compound 130) is applied, in which case the mold compound at least partially encapsulates the second die.

In some examples, at least one of the dies may be electrically coupled to a respective substrate after applying the mold compound. For example, the first die (e.g., the die 108) can be electrically coupled to the first contacts (e.g., the contacts 110) of the first substrate (e.g., the package substrate 102) after the mold compound (e.g., the mold compound 130) is applied, in which case the mold compound is selectively applied such that, after the mold compound is applied, the first contacts are exposed in a region associated with the first die. Additionally, or alternatively, the second die (e.g., the die 140) can be electrically coupled to the second contacts (e.g., the contacts 120) of the second substrate (e.g., the package substrate 112) after the mold compound (e.g., the mold compound 130) is applied, in which case the mold compound is selectively applied such that, after the mold compound is applied, the second contacts are exposed in a region (e.g., the region 118) associated with the second die.

In some examples, the method 500 includes separating the first substrate and the second substrate from the carrier after said applying the mold compound. For example, Stage 7A of FIG. 4B and Stage 6B of FIG. 4D illustrate and describe operations to separate the package substrate 102 and the package substrate 112 from the carrier 410 after the mold compound 130 is applied. In embodiments in which operations to form two or more integrated device packages are performed concurrently (e.g., as strip-level or panel-level operations), the method 500 can also include individuating sets of substrates and wirebond interconnects after the mold compound is applied. In this context, individuating refers to separating the substrates and the mold compound of one integrated device package from one or more other components. For example, Stage 7A of FIG. 4B and Stage 6B of FIG. 4D illustrate and describe operations to individuate respective assemblies 430 and 470 after the package substrates 102, 112 and the mold compound 130 are separated from the carrier 410.

In some examples, the method 500 also includes coupling a support structure to a bottom surface of the first substrate and a bottom surface of the second substrate. For example, Stage 8A of FIG. 4C and Stage 7B of FIG. 4D illustrate and describe operations to couple the support structure(s) 132 to a bottom surface of the package substrate 102 and a bottom surface of the package substrate 112.

In some examples, the method 500 also includes forming off-package interconnects on a bottom surface of the first substrate and on a bottom surface of the second substrate after separating the first substrate and the second substrate from the carrier. For example, Stage 9A of FIG. 4C and Stage 8B of FIG. 4D illustrate and describe operations to form the off-package interconnects 142 on a bottom surface of the package substrate 102 and on a bottom surface of the package substrate 112.

### Exemplary Electronic Devices

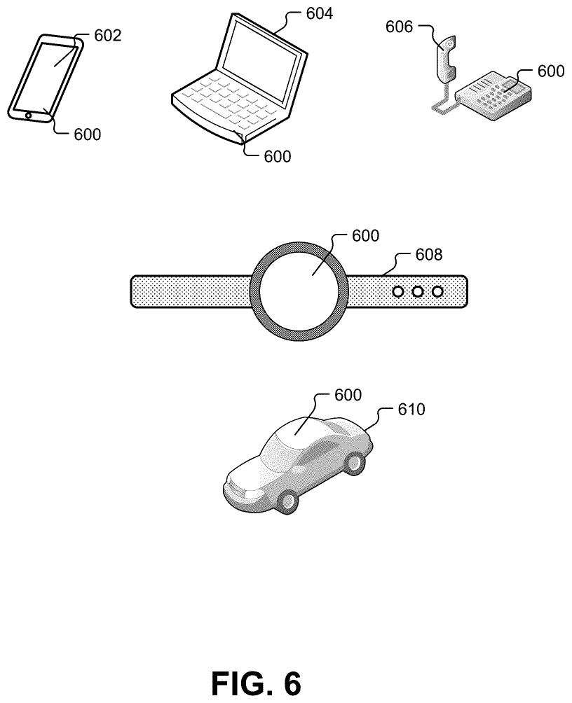

FIG. 6 illustrates various electronic devices that may include or be integrated with the integrated device packages 100, 150, 190 with wirebond interconnects of any of FIG. 1-3, 4C or 4D. For example, a mobile phone device 602, a laptop computer device 604, a fixed location terminal device 606, a wearable device 608, or a vehicle 610 (e.g., an automobile or an aerial device) may include a device 600. The device 600 can include, for example, any of the integrated device packages 100, 150, 190 described herein. The devices 602, 604, 606 and 608 and the vehicle 610 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-6 may be rearranged and/or combined into a single component, process, feature or function or embodied in several components, processes, or functions. Additional elements, components, processes, and/or functions may also be added without departing from the disclosure. It should also be noted FIGS. 1-6 and its corresponding description in the present disclosure is not limited to dies and/or ICs. In some implementations, FIGS. 1-6 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first,” “second,” “third,” and “fourth” (and/or anything above fourth) is arbitrary. Any of the components described may be the first component, the second component, the third component or the fourth component. For example, a component that is referred to as a second component, may be the first component, the second component, the third component or the fourth component. The terms “encapsulate,” “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X,’” or “approximately value X,” as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes a first substrate comprising a first set of conductors that define first contacts for a first die and first conductive interconnects to route signals associated with the first die; a second substrate comprising a second set of conductors that define second contacts for a second die and second conductive interconnects to route signals associated with the second die; a set of wirebond interconnects electrically coupled to the first set of conductors and the second set of conductors; and mold compound that at least partially encapsulates the first substrate, the second substrate, and the set of wirebond interconnects, wherein the mold compound is configured to retain the first substrate and the second substrate in position relative to one another in a side-by-side configuration.

Example 2 includes the device of Example 1, wherein the first substrate has a first thickness and the second substrate has a second thickness different from the first thickness.

Example 3 includes the device of Example 1 or Example 2, wherein the first substrate has a first count of metal layers and the second substrate has a second count of metal layers, and wherein the first count is equal to the second count.

Example 4 includes the device of any of Examples 1 to 3 and further includes the first die coupled to the first substrate and the second die coupled to the second substrate, wherein signal paths between the first die and the second die include the set of wirebond interconnects.

Example 5 includes the device of any of Examples 1 to 4, wherein the first die comprises one or more processor cores and the second die comprises one or more memory cells accessible to the one or more processor cores via the set of wirebond interconnects.

Example 6 includes the device of any of Examples 1 to 5, wherein the second contacts are arranged according to a JEDEC Solid State Technology Association specification for double data rate (DDR) dynamic random access memory (DRAM) interconnection.

Example 7 includes the device of any of Examples 1 to 6, wherein the first substrate comprises a metal-prepreg composite stack and the second substrate comprises a set of redistribution layers.

Example 8 includes the device of any of Examples 1 to 7 and further includes a third substrate comprising a third set of conductors that define third contacts for a third die and third conductive interconnects to route signals associated with the third die; and a second set of wirebond interconnects electrically coupled to the first set of conductors and the third set of conductors; wherein the mold compound is configured to retain the first substrate, the second substrate, and the third substrate in position relative to one another in the side-by-side configuration.

Example 9 includes the device of any of Examples 1 to 8 and further includes first off-package contacts coupled to a bottom of the first substrate; and second off-package contacts coupled to a bottom of the second substrate.

Example 10 includes the device of any of Examples 1 to 9, wherein a bottom surface of the first substrate is substantially co-planar with a bottom surface of the second substrate.

Example 11 includes the device of any of Examples 1 to 10 and further includes a support structure coupled to a bottom surface of the first substrate and a bottom surface of the second substrate.

According to Example 12, a method of fabrication includes arranging a first substrate and a second substrate side-by-side on a carrier, wherein the first substrate comprises a first set of conductors that define first contacts for a first die and first conductive interconnects to route signals associated with the first die and the second substrate comprises a second set of conductors that define second contacts for a second die and second conductive interconnects to route signals associated with the second die; electrically coupling a set of wirebond interconnects between the first set of conductors and the second set of conductors; and applying a mold compound to at least partially encapsulate the first substrate, the second substrate, and the set of wirebond interconnects to retain the first substrate and the second substrate in position relative to one another in a side-by-side configuration.

Example 13 includes the method of Example 12 and further includes, before said applying the mold compound, electrically coupling the first die to the first contacts of the first substrate.

Example 14 includes the method of Example 12 or Example 13 and further includes, before said applying the mold compound, electrically coupling the second die to the second contacts of the second substrate.

Example 15 includes the method of Example 12 or Example 13 and further includes, after said applying the mold compound, electrically coupling the second die to the second contacts of the second substrate.

Example 16 includes the method of any of Examples 12 to 15 and further includes, after said applying the mold compound, separating the first substrate and the second substrate from the carrier.

Example 17 includes the method of Example 16 and further includes, after said separating the first substrate and the second substrate from the carrier, separating the first substrate, the second substrate, and the mold compound from one or more other components.

Example 18 includes the method of Examples 16 and further includes, after said separating the first substrate and the second substrate from the carrier, forming off-package interconnects on a bottom surface of the first substrate and on a bottom surface of the second substrate.

Example 19 includes the method of any of Examples 12 to 18, wherein the mold compound is selectively applied such that the second contacts are not covered by the mold compound.

Example 20 includes the method of any of Examples 12 to 19 and further includes coupling a support structure to a bottom surface of the first substrate and a bottom surface of the second substrate.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a first substrate comprising a first set of conductors that define first contacts for a first die and first conductive interconnects to route signals associated with the first die;
a second substrate comprising a second set of conductors that define second contacts for a second die and second conductive interconnects to route signals associated with the second die;
a set of wirebond interconnects electrically coupled to the first set of conductors and the second set of conductors; and
mold compound that at least partially encapsulates the first substrate, the second substrate, and the set of wirebond interconnects, wherein the mold compound is configured to retain the first substrate and the second substrate in position relative to one another in a side-by-side configuration.

2. The device of claim 1, wherein the first substrate has a first thickness and the second substrate has a second thickness different from the first thickness.

3. The device of claim 2, wherein the first substrate has a first count of metal layers and the second substrate has a second count of metal layers, and wherein the first count is equal to the second count.

4. The device of claim 1, further comprising the first die coupled to the first substrate and the second die coupled to the second substrate, wherein signal paths between the first die and the second die include the set of wirebond interconnects.

5. The device of claim 4, wherein the first die comprises one or more processor cores and the second die comprises one or more memory cells accessible to the one or more processor cores via the set of wirebond interconnects.

6. The device of claim 1, wherein the second contacts are arranged according to a Joint Electron Device Engineering Council (JEDEC) Solid State Technology Association specification for double data rate (DDR) dynamic random access memory (DRAM) interconnection.

7. The device of claim 1, wherein the first substrate comprises a metal-prepreg composite stack and the second substrate comprises a set of redistribution layers.

8. The device of claim 1, further comprising:
a third substrate comprising a third set of conductors that define third contacts for a third die and third conductive interconnects to route signals associated with the third die; and
a second set of wirebond interconnects electrically coupled to the first set of conductors and the third set of conductors;
wherein the mold compound is configured to retain the first substrate, the second substrate, and the third substrate in position relative to one another in the side-by-side configuration.

9. The device of claim 1, further comprising:
first off-package contacts coupled to a bottom of the first substrate; and
second off-package contacts coupled to a bottom of the second substrate.

10. The device of claim 1, wherein a bottom surface of the first substrate is substantially co-planar with a bottom surface of the second substrate.

11. The device of claim 1, further comprising a support structure coupled to a bottom surface of the first substrate and a bottom surface of the second substrate.

12. A method of fabrication comprising
arranging a first substrate and a second substrate side-by-side on a carrier, wherein the first substrate comprises a first set of conductors that define first contacts for a first die and first conductive interconnects to route signals associated with the first die and the second substrate comprises a second set of conductors that define second contacts for a second die and second conductive interconnects to route signals associated with the second die;
electrically coupling a set of wirebond interconnects between the first set of conductors and the second set of conductors; and
applying a mold compound to at least partially encapsulate the first substrate, the second substrate, and the set of wirebond interconnects to retain the first substrate and the second substrate in position relative to one another in a side-by-side configuration.

13. The method of claim 12, further comprising, before said applying the mold compound, electrically coupling the first die to the first contacts of the first substrate.

14. The method of claim 13, further comprising, before said applying the mold compound, electrically coupling the second die to the second contacts of the second substrate.

15. The method of claim 13, further comprising, after said applying the mold compound, electrically coupling the second die to the second contacts of the second substrate.

16. The method of claim 12, further comprising, after said applying the mold compound, separating the first substrate and the second substrate from the carrier.

17. The method of claim 16, further comprising, after said separating the first substrate and the second substrate from the carrier, separating the first substrate, the second substrate, and the mold compound from one or more other components.

18. The method of claim 16, further comprising, after said separating the first substrate and the second substrate from the carrier, forming off-package interconnects on a bottom surface of the first substrate and on a bottom surface of the second substrate.

19. The method of claim 12, wherein the mold compound is selectively applied such that the second contacts are not covered by the mold compound.

20. The method of claim 12, further comprising coupling a support structure to a bottom surface of the first substrate and a bottom surface of the second substrate.
